(19) United States
(12) Patent Application Publication
(10) Pub. No.: US 2023/0087188 A1
(43) Pub. Date: Mar. 23, 2023

(54) PLASMA ETCHING METHOD, PLASMA ETCHING APPARATUS, AND SEMICONDUCTOR DEVICE MANUFACTURING METHOD

(71) Applicant: Kioxia Corporation, Tokyo (JP)

(72) Inventors: Hiroyuki FUKUMIZU, Yokohama (JP); Shuichi KUBOI, Yokohama (JP); Abhishek THOTE, Yokohama (JP)

(73) Assignee: Kioxia Corporation, Tokyo (JP)

(21) Appl. No.: 17/644,154

(22) Filed: Dec. 14, 2021

(30) Foreign Application Priority Data
Sep. 17, 2021 (JP) 2021-152578

(51) Int. Cl. H01L 21/311; H01L 21/3065; H01L 21/02; H01J 37/32

(52) U.S. Cl. CPC H01L 21/31116; H01L 21/3065; H01L 21/0212; H01L 21/31144; H01J 37/32449; H01J 2237/334

(57) ABSTRACT

A plasma etching method of an embodiment includes etching a silicon-containing film using plasma of a fluorocarbon gas. The fluorocarbon gas contains fluorocarbon which has a composition, regarding carbon and fluorine, represented by a general formula: CₓF_{y}, where x and y are numbers satisfying x≥12 and x≥y, and which includes two benzene rings bonded through a C—C single bond.

### CROSS REFERENCE TO RELATED APPLICATION

This application is based upon and claims the benefit of priority from Japanese Patent Application No. 2021-152578, filed on Sep. 17, 2021; the entire contents of which are incorporated herein by reference.

### FIELD

Embodiments of the present invention relate to a plasma etching method, a plasma etching apparatus, and a semiconductor device manufacturing method.

### BACKGROUND

In a semiconductor device manufacturing process, plasma etching is performed to form contact holes, via holes, trenches (grooves), and so on in a silicon-containing film such as a silicon oxide film formed on a semiconductor substrate or the like. In such a semiconductor device manufacturing process, the precise control of a processing shape, in particular, the vertical processing of sidewalls of contact holes is important for the semiconductor device to surely have electrical performance and the like. For example, a recent three-dimensionally structured device has a hole with a high aspect ratio. In the formation of the hole with a high aspect ratio by plasma etching, it is desired to increase a processing selection ratio of a film to be processed with respect to a base film.

### BRIEF DESCRIPTION OF THE DRAWINGS

FIG. 1 is a sectional view of a plasma etching apparatus of an embodiment.

FIG. 2 is a chart illustrating examples of a fluorocarbon gas used in a plasma etching method of the embodiment.

FIG. 3 is a table showing percentages of gas cracked species of the fluorocarbon gas used in the plasma etching method of the embodiment.

FIG. 4 is a view for explaining the shapes and dimensions (x, y, and D) of a deposition film on an etching mask and an etching hole in the plasma etching method of the embodiment.

FIG. 5 is a chart illustrating a relation between a C/F ratio of the fluorocarbon gas used in the plasma etching method of the embodiment and a y/x ratio of the deposition film illustrated in FIG. 4.

FIG. 6 is a chart illustrating a relation between the C/F ratio of the fluorocarbon gas used in the plasma etching method of the embodiment and the etching depth D of a metal film illustrated in FIG. 4.

FIG. 7 is a sectional view of a semiconductor device manufactured using the plasma etching method of the embodiment.

### DETAILED DESCRIPTION

A plasma etching method according to an embodiment includes etching a silicon-containing film using plasma of a fluorocarbon gas. The fluorocarbon gas contains fluorocarbon which has a composition, regarding carbon and fluorine, represented by a general formula: CₓF_{y},

where x and y are numbers satisfying x≥12 and x≥y, and

which includes two benzene rings bonded through a C—C single bond.

Hereinafter, a plasma etching method, a plasma etching apparatus, and a semiconductor device manufacturing method of embodiments will be described with reference to the drawings. In the embodiments, substantially the same constituent parts are denoted by the same reference signs and a description thereof may be partly omitted. The drawings are schematic, and a relation of thickness and planar dimension, a thickness ratio among parts, and so on may be different from actual ones. In the description, a term expressing a direction such as the up-down direction indicates a relative direction when a surface to be plasma-etched (surface to be processed) of a later-described substrate is defined as an upper side unless otherwise specified and may be different from an actual direction based on a gravitational acceleration direction.

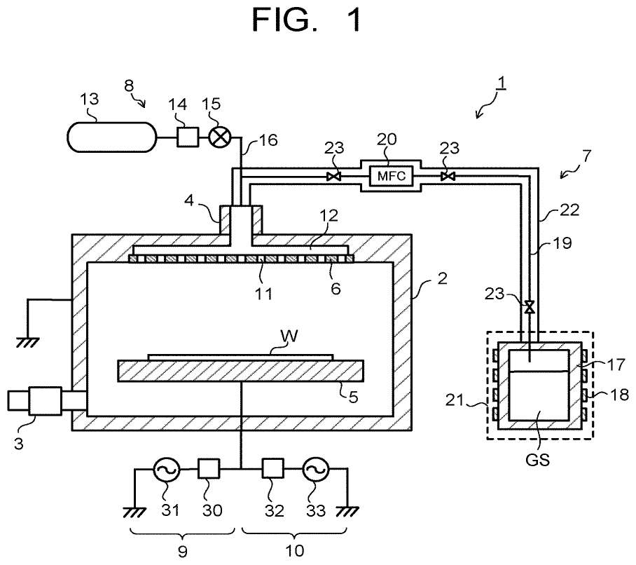

FIG. 1 is a sectional view of a plasma etching apparatus according to an embodiment. The plasma etching apparatus 1 illustrated in FIG. 1 is a parallel plate-type RIE (Reactive Ion Etching) apparatus and includes a chamber 2, an exhaust port 3, a process gas inlet 4, a lower electrode (substrate electrode) 5, an upper electrode (counter electrode) 6, a first process gas introducing system 7, a second process gas introducing system 8, a first power supply system 9, and a second power supply system 10.

The chamber 2 is provided with the exhaust port 3 and the process gas inlet 4. The exhaust port 3 is connected to a pressure-regulating valve, an exhaust pump, and so on which are not illustrated. Gas in the chamber 2 is discharged from the exhaust port 3 so that the inside of the chamber 2 is kept at a high vacuum. Further, when a process gas is introduced from the process gas inlet 4, the flow rate of the gas flowing in from the process gas inlet 4 and the flow rate of the gas flowing out from the exhaust port 3 are balanced so that the pressure in the chamber 2 can be kept at a constant vacuum pressure.

The first process gas introducing system 7 and the second process gas introducing system 8 are connected to the process gas inlet 4 of the chamber 2. In the chamber 2, a gas introduction space 12 facing a plurality of gas jetting ports 11 of the upper electrode 6 is further provided and is connected to the process gas inlet 4. The first process gas introducing system 7 has a mechanism for vaporizing a process gas raw material that is solid at room temperature and introducing the resultant into the chamber 2. The second process gas introducing system 8 introduces, into the chamber 2, a process gas that is gaseous at room temperature, and includes a gas supply source 13, a mass flow controller 14 which controls a gas flow rate, an opening/closing valve 15, and a pipe 16. The pipe 16 has one end connected to the gas supply source 13 and the other end connected to the process gas inlet 4. Examples of the process gas that is gaseous at room temperature include rare gases such as He, Ar, Kr, and Xe, gases such as N₂, O₂, H₂, CO, NF₃, SF₆, and CH₄, typical CₓF_{y} gases such as CF₄, C₄F₆, and C₄F₈, and CₓH_{y}F_{z} gases such as CHF₃, CH₂F₂, and CH₃F.

The first process gas introducing system 7 includes a raw material tank 17 storing the process gas raw material GS that is solid at room temperature, heater 18 which is provided around the raw material tank 17 and heat the process gas raw material GS that is solid at room temperature, stored in the raw material tank 17 to cause the generation of a vaporized component of the process gas raw material GS, a pipe 19 which leads the vaporized component of the process gas raw material GS up to the process gas inlet 4, and a gas flow rate controller 20 such as a mass flow controller (MFC) provided in the middle of the pipe 19 extending from the raw material tank 17 up to the process gas inlet 4. The pipe 19 has one end open toward the inside of the raw material tank 17 and the other end connected to the process gas inlet 4. The peripheries of the heaters 18 provided around the raw material tank 17 are covered with a heat insulator 21. A heater 22 is provided around the pipe 19 extending from the raw material tank 17 up to the process gas inlet 4. The pipe 19 is provided with opening/closing valves 23 at predetermined places.

In the first process gas introducing system 7, the process gas raw material GS that is solid at room temperature is stored in the raw material tank 17, and the heater 18 provided around the raw material tank 17 heats the process gas raw material GS, thereby generating the vaporized component of the process gas raw material GS. The vaporized component of the process gas raw material GS is sent to the gas flow rate controller 20 through the pipe 19. The vaporized component of the process gas raw material GS whose flow rate has been controlled by the gas flow rate controller 20 is sent into the chamber 2 through the process gas inlet 4 at a predetermined gas flow rate. The solid process gas raw material GS and its vaporized component will be described in detail later.

In the chamber 2, the lower electrode 5 as the substrate electrode is provided which is vertically movable and also serves as a mounting table (holding part) where to place a substrate such as a semiconductor wafer W. In an upper part of the lower electrode 5, a not-illustrated electrostatic chuck is provided so that the semiconductor wafer W can be held on the lower electrode 5. Above the lower electrode 5, the upper electrode 6 which is the counter electrode and also serves as a showerhead for jetting the process gas is disposed at a position where it separates the gas introduction space 12 and a processing space where to etch the semiconductor wafer W. In the upper electrode 6, the gas jetting ports 11 are provided so that the process gas can be supplied from the gas introduction space 12 to the space where to process the semiconductor wafer W. The chamber 2 is grounded.

The first power supply system 9 and the second power supply system 10 are connected to the lower electrode 5 which is the substrate electrode. The first power supply system 9 includes a matching device 30 and a first high-frequency power source 31. The second power supply system 10 includes a matching device 32 and a second high-frequency power source 33. The first high-frequency power source 31 outputs a first high-frequency voltage (Va) for ionizing the process gas and generating plasma, and the output first high-frequency voltage (Va) is applied to the lower electrode 5. The second high-frequency power source 33 outputs a second high-frequency voltage (Vb) lower in frequency than the first high-frequency voltage (Va) and for attracting the ions from the plasma to the semiconductor wafer W, and the output second high-frequency voltage (Vb) is applied to the lower electrode 5. The voltage Va and the voltage Vb are both generally called high frequency, but to explain a frequency difference between these, the first high-frequency voltage (Va) and the second high-frequency voltage (Vb) will be referred to as an RF high-frequency voltage and an RF low-frequency voltage respectively for convenience' sake.

To have a high plasma generation power, the RF high-frequency voltage (Va) output by the first high-frequency power source 31 preferably has a frequency of 27 MHz or more, and preferable examples of its frequency include 100 MHz, 60 MHz, 40 MHz, and 27 MHz. To have a high ion attracting property, the RF low-frequency voltage (Vb) output by the second high-frequency power source 33 preferably has a frequency of 3 MHz or less, and preferable examples of its frequency include 3 MHz, 2 MHz, 400 kHz, and 100 kHz. A voltage between upper and lower peaks of the RF low-frequency voltage (Vb) applied to the lower electrode 5 from the second high-frequency power source 33 is preferably 1000 V or more.

The RF high-frequency voltage (Va) from the first high-frequency power source 31 and the RF low-frequency voltage (Vb) from the second high-frequency power source 33 which are described above are applied to the lower electrode 5 at the same time when the process gas is introduced into the chamber 2 from the first process gas introducing system 7, and as necessary, when the process gas is introduced into the chamber 2 from the second process gas introducing system 8, resulting in the generation of the plasma between the lower electrode 5 and the upper electrode 6. That is, the RF high-frequency voltage (Va) from the first high-frequency power source 31 and the RF low-frequency voltage (Vb) from the second high-frequency power source 33 are applied to the lower electrode 5 in a superimposed manner, thereby ionizing the process gas to form the plasma of the process gas between the lower electrode 5 and the upper electrode 6, and at the same time, attracting the ions to the lower electrode 5 side.

Next, a plasma etching method of the semiconductor wafer W using the above-described plasma etching apparatus 1 will be described. In the plasma etching method of the embodiment, a substrate such as the semiconductor wafer W that is to be etched is first placed on the lower electrode 5. The semiconductor wafer W to be etched has a silicon-containing film, such as a silicon oxide film (SiO film) and a silicon nitride film (SiN film), formed on a base layer, such as a semiconductor film or a metal film (a base film) containing at least one selected from a group consisting of silicon, tungsten, aluminum, titanium, molybdenum, and tantalum. An etching mask is formed on the semiconductor wafer W having such a silicon-containing film such as the SiO film and the SiN film, and an opening (mask hole: MH) is formed by the patterning of the etching mask. Next, by the etching of the silicon-containing film on which the etching mask is formed, a hole (etching hole: EH) such as a contact hole corresponding to the opening (MH) of the etching mask is formed in the silicon-containing film.

In the formation of the etching hole EH such as the contact hole in the silicon-containing film, at the same time when the process gas is introduced into the chamber 2 from the first process gas introducing system 7, the RF high-frequency voltage (Va) from the first high-frequency power source 31 and the RF low-frequency voltage (Vb) from the second high-frequency power source 33 are applied to the lower electrode 5 on which the semiconductor wafer W having the etching mask thereon is placed. This results in the generation of the plasma between the lower electrode 5 and the upper electrode 6 and the attraction of the ions in the plasma to the semiconductor wafer W, so that the silicon-containing film is etched. The etching of the silicon-containing film is applied to the SiO film, for instance. The silicon-containing film to be plasma-etched is not limited to a single film of a SiO film but may be a stacked film of a SiO film and a SiN film. In the plasma etching of the silicon-containing film, the silicon-containing film can be selectively processed based on a difference in etching rate between the silicon-containing film and the aforesaid base film such as the semiconductor film or the metal film.

In the above-described plasma etching of the silicon-containing film, the process gas raw material GS stored in the raw material tank 17 of the first process gas introducing system 7 contains fluorocarbon that has a composition, regarding carbon and fluorine, represented by

a general formula: CₓF_{y} (1),

where x and y are numbers satisfying x≥12 and x≥y, and
that has, in its molecular skeleton, two benzene rings bonded through a C—C single bond. Since such fluorocarbon is solid at room temperature, the mechanism, illustrated in FIG. 1, for vaporizing the solid process gas raw material GS is used. The fluorocarbon used in the plasma etching contains the vaporized component of the process gas raw material GS.

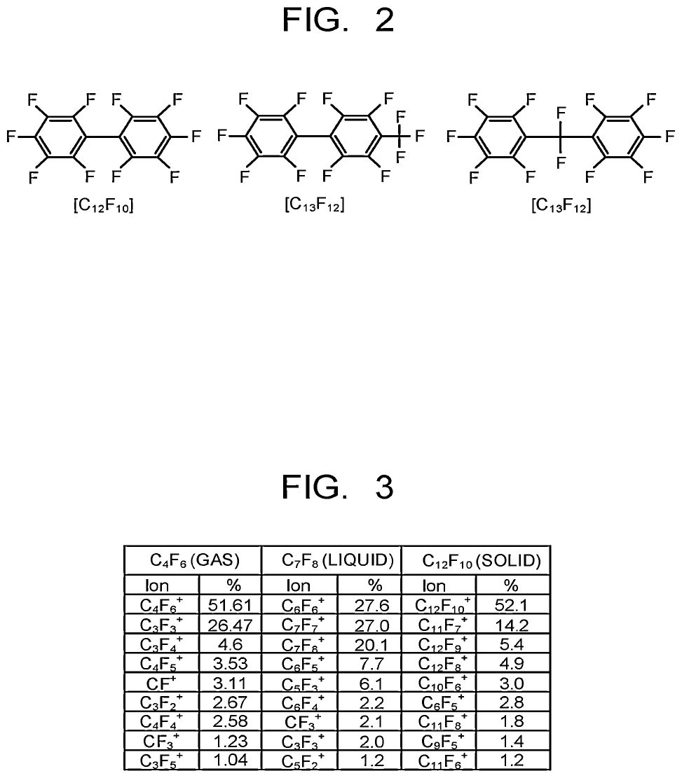

FIG. 2 illustrates specific examples of the fluorocarbon used in the embodiment. Examples of the fluorocarbon satisfying the aforesaid composition formula (1) and having the structure in which the two benzene rings are bonded through the C—C single bond include C₁₂F₁₀ and C₁₃F₁₂ as illustrated in FIG. 2. C₁₂F₁₀ and C₁₃F₁₂ each have the structure in which two benzene rings are bonded through a C—C single bond. The bond structure of the two benzene rings is not limited to the structure in which the carbons of the two benzene rings are bonded through the C—C single bond and may be a structure in which they are bonded through, for example, a carbon difluoride group (—CF₂—) which is a divalent carbon fluoride group. In this case as well, two carbons of the two benzene rings are bonded through two C—C single bonds through C of the carbon fluoride group.

The fluorocarbon used in the embodiment has a structure in which F's are bonded to C's of the benzene ring structure whose two benzene rings are bonded only through the C—C single bond, a structure in which F's are bonded to part of C's of the benzene ring structure whose two benzene rings are bonded through the C—C single bond and a monovalent carbon fluoride group (—CF₃) is bonded to another part of C's, or a structure in which the two benzene rings having at least part of C's bonded to F's are bonded through a divalent carbon fluoride group (—CF₂— or the like). That is, in the fluorocarbon used in the embodiment, the two benzene rings may be bonded only through one C—C single bond or may be bonded through a group mainly composed of C, such as the divalent carbon fluoride group (—CF₂—) including C—C single bonds. Further, a monovalent carbon fluoride (—CF₃) may be bonded to part of C's of the two benzene rings.

The fluorocarbon used in the embodiment has the two benzene rings or more as described above and has a composition in which the number x of carbons (C) is equal to or more than the number y of fluorines (F). That is, the fluorocarbon has the two benzene rings or more and has the composition in which a carbon (C)/fluorine (F) ratio is 1 or more, or further the C/F ratio exceeds 1. Based on such a composition, it is possible to improve a processing selection ratio of the film to be processed with respect to the base film and enhance the vertical deposition property of a deposition film formed on the etching mask.

The fluorocarbon used in the embodiment is not limited to perfluorocarbon and may be a compound partly replaced with hydrogen or oxygen. The aforesaid fluorocarbon may be one not only having the composition represented by CₓF_{y} but also represented by a composition formula further containing one H or O or more. However, the fluorocarbon used in the embodiment is preferably perfluorocarbon compound because fluorocarbon containing hydrogen (H) or the like lowers processing selectivity. The C/F ratio in the aforesaid composition formula preferably exceeds 1 because a component with a large C/F generated in plasma leads to an excellent etching effect.

The aforesaid fluorocarbon will be described in detail below. Typically, in plasma, gas is cracked by its collides with electrons. FIG. 3 shows percentages of gas cracked species generated by the collision of electrons with the fluorocarbon gas used in the embodiment and with fluorocarbon gases of comparative examples. FIG. 3 shows the percentages of cracked species of C₁₂F₁₀ which is a typical example of the fluorocarbon gas used in the embodiment and C₄F₆ and C₇F₈ which are typical examples of the fluorocarbon gases of the comparative examples. In C₄F₆ of the comparative example, four carbons are bonded through double bonds and single bond, and in C₇F₈ of the comparative example, a monovalent carbon fluoride group (—CF₃) is bonded to one benzene ring. As is seen from the table in FIG. 3, various cracked species are generated from C₄F₆ and C₇F₈, but from C₁₂F₁₀, which is not easily cracked in plasma, a cracked species having a structure close to the mother structure of the fluorocarbon is generated at a high percentage. That is, the use of the fluorocarbon in which the two benzene rings are bonded through the C—C single bond makes it possible to increase a generation percentage of C-rich radicals that have the structure close to the mother structure with high C/F and that has no electric charge.

The aforesaid radicals having the structure close to the mother structure of the fluorocarbon having the two benzene rings and having the composition with a C/F ratio of 1 or more enables an increase in the vertical deposition property of the adherent (deposition film) formed on the etching mask. This makes it possible to etch the film to be processed while avoiding the closing of the mask hole MH formed in the etching mask. That is, it is possible to favorably form the etching hole EH with a large aspect ratio in the silicon-containing film which is the film to be processed. Further, the aforesaid C-rich radicals having the structure close to the mother structure enter the bottom of the etching hole EH, facilitating the accumulation of the component containing carbon on the base film such as the metal layer or the semiconductor layer which is a lower layer of the film to be processed. This makes it possible to increase the processing selection ratio of the silicon-containing film being the film to be processed with respect to the base film.

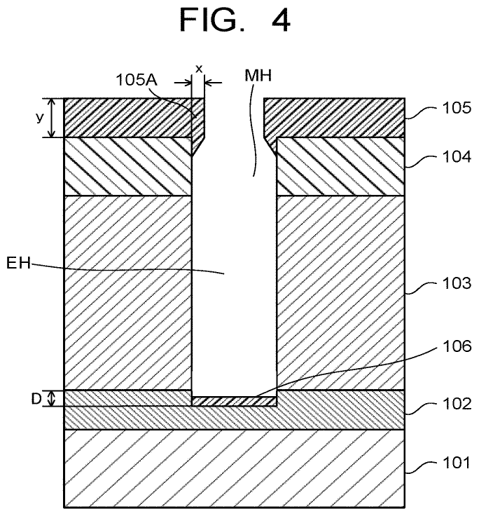

An etching step using the aforesaid fluorocarbon and its result will be described with reference to FIG. 4 to FIG. 6. FIG. 4 is a view for explaining the shapes and dimensions of a deposition film on the etching mask and an etching hole in the plasma etching method of the embodiment. In FIG. 4, a metal film 102 is on a silicon substrate 101, and a silicon-containing film 103 which is a film to be processed is on the metal film 102. On the silicon-containing film 103, an etching mask 104 is formed, and the etching mask 104 has a mask hole MH therein. The silicon-containing film 103 is plasma-etched using such an etching mask 104 having the mask hole MH, whereby an etching hole EH corresponding to the mask hole MH is formed in the silicon-containing film 103. A component of the fluorocarbon in the plasma is deposited on the etching mask 104 to form a deposition film 105. The component of the fluorocarbon is also deposited on the bottom of the etching hole EH to form a deposition film 106.

In FIG. 4, a mask hole MH-side end 105A of the deposition film 105 protrudes toward the mask hole MH. A high y/x ratio, where x is a protrusion width of the end 105A toward the mask hole MH and y is the thickness of the deposition film 105, indicates that the vertical deposition property of the deposition component of the fluorocarbon is high and the closing of the mask hole M is avoided and thus the formability of the etching hole EH is high. A shallow depth D, where D is the depth of an etching hole EH of the metal film 102 which etching hole EH continues from the bottom of the etching hole EH formed in the silicon-containing film 103, indicates a high processing selection ratio of the silicon-containing film 103 and excellent processability of the silicon-containing film 103 on the metal film 102.

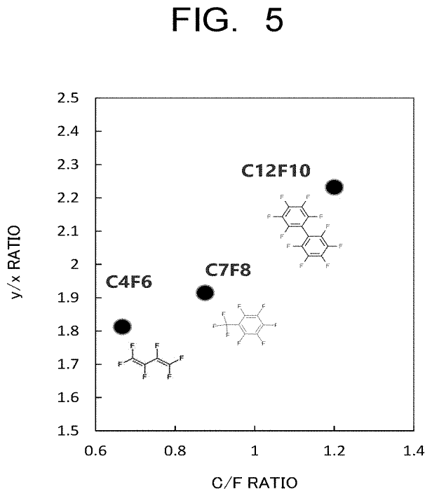

FIG. 5 illustrates the y/x ratio in the cases where, as the fluorocarbon from which the radicals are generated in the plasma, C₁₂F₁₀ according to the embodiment is used and C₄F₆ and C₇F₈ of the comparative examples are used. As is seen from FIG. 5, C₁₂F₁₀ has a high C/F ratio and has a large C content per molecule and thus achieves an excellent vertical deposition property at the time of the plasma etching and a higher y/x ratio than C₄F₆ and C₇F₈ of the comparative examples. Increasing the y/x ratio makes it possible to favorably etch the silicon-containing film 103 which is the film to be processed while avoiding the closing of the mask hole MH formed in the etching mask 104.

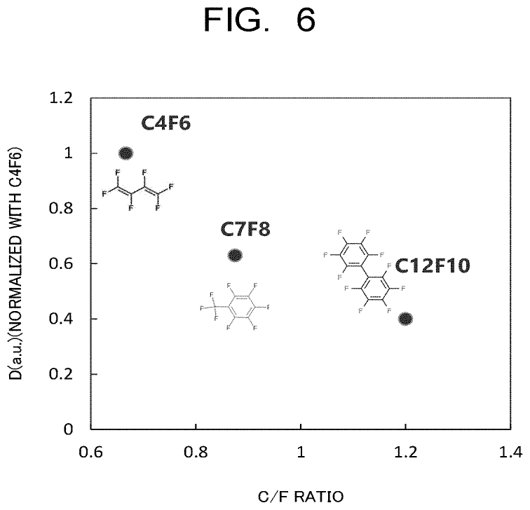

FIG. 6 illustrates the depth D which corresponds to the etching amount of the metal film 102 in the cases where, as the fluorocarbon from which the radicals are generated in the plasma, C₁₂F₁₀ according to the embodiment is used and C₄F₆ and C₇F₈ of the comparative examples are used. The depth D in FIG. 6 is a value normalized with the depth D when C₄F₆ is used for the etching. As illustrated in FIG. 6, C₁₂F₁₀, which has a high C/F ratio and contains a large amount of C per molecule, can increase the deposition amount of the component containing carbon (deposition amount of the deposition film 106) on the bottom of the etching hole EH, thereby capable of making the hole depth D of the metal film 102 small. That is, it is possible to increase the processing selection ratio of the silicon-containing film.

As illustrated in FIG. 5 and FIG. 6, from the fluorocarbon used in the embodiment, the cracked species with a large molecular weight and a high C/F ratio is easily generated in the plasma as described above because it contains, in its main chain, the benzene rings including carbon-carbon double bonds that are conjugate and difficult to dissociate. This leads to an excellent vertical deposition property of the adherent (deposition film) at the time of the plasma etching, making it possible to etch the film to be processed while avoiding the closing of the mask hole MH formed in the etching mask. Further, since many ions with a high C/F ratio enter the bottom of the etching hole EH, it is possible to improve the processing selection ratio with respect to the base film while maintaining a high etching yield, leading to an excellent etching effect. With the above-described fluorocarbon, it is possible to obtain an excellent processing selection ratio with respect to the base film, and increase plasma application power while maintaining the processing selection ratio with respect to the base film. Therefore, it is possible to increase a hole etching rate in the etching of the silicon-containing film 103 formed on the semiconductor wafer W.

That is, according to the fluorocarbon gas containing the vaporized component of the fluorocarbon used in the embodiment, it is possible to obtain a good hole etching rate and also increase the processing selection ratio of the silicon-containing film with respect to the base film. Because of these, it is possible to increase the plasma application power while maintaining the state and so on of the metal layer or the semiconductor layer serving as the base film of the silicon-containing film. This enables the accurate and efficient formation of a contact hole or the like with a large aspect ratio in, for example, a SiO film or a stacked film of a SiO film and a SiN film. Further, having a higher etching rate of the silicon-containing film than an etching rate of the metal film of tungsten (W) or the like, the above-described fluorocarbon gas containing the vaporized component of the fluorocarbon can selectively process the silicon-containing film in the etching of the silicon-containing film formed on the metal film such as the W

Involving the C—C single bond between the two benzene rings, the above-described fluorocarbon can more promote the cracking caused by electron collision in the plasma and starting from the C—C single bond than a naphthalene-based fluorocarbon gas whose molecular skeleton substantially entirely has a conjugate ring structure, such as, for example, C₁₀F₈ (octafluoronaphthalene) having no C—C single bond. The radicals and ions large in molecular weight and high in the C/F ratio are easily generated. Accordingly, with the fluorocarbon used in the embodiment, it is possible to make the ions stably enter the bottom of the etching hole EH even if the etching hole EH is deep, making it possible to form a hole with a high aspect ratio while maintaining excellent processability.

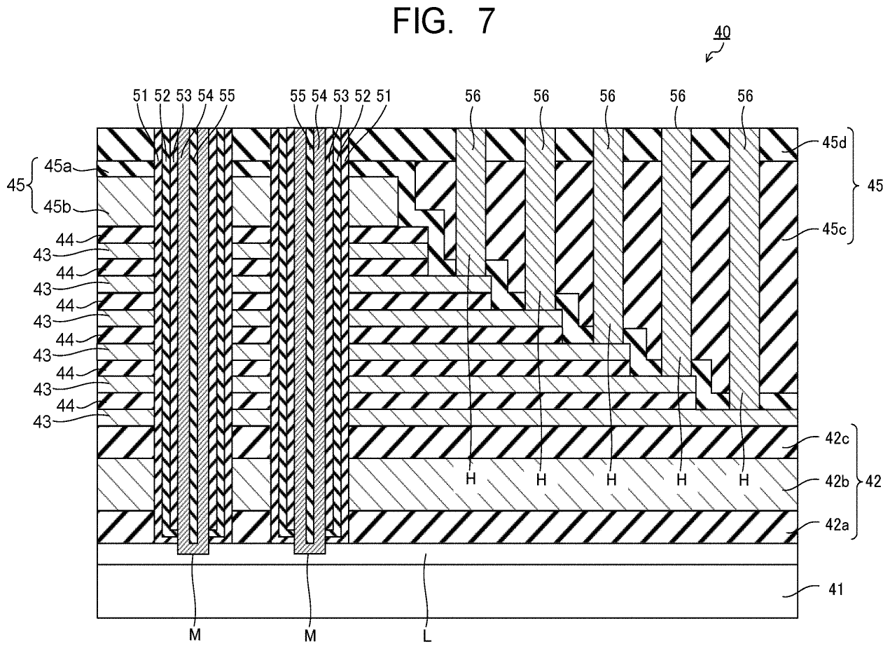

The above-described plasma etching method of the embodiment is applied to, for example, a semiconductor device manufacturing process. FIG. 7 is a sectional view of a semiconductor device 40 manufactured using the plasma etching method of the embodiment. The semiconductor device 40 illustrated in FIG. 7 is a three-dimensionally stacked nonvolatile memory device and includes a substrate 41, a lower layer 42, a plurality of electrode layers 43, a plurality of insulating layers 44, an upper layer 45, a plurality of memory holes M, and a plurality of contact holes H. The semiconductor device 40 further includes a block insulating film 51, a charge storage film 52, a tunnel insulating film 53, a channel semiconductor layer 54, and a core insulating film 55 which are provided in sequence in each of the memory holes M, and contact plugs 56 provided in the contact holes H.

The substrate 41 is a semiconductor substrate such as a silicon (Si) substrate, for instance. The lower layer 42 on the substrate 41 is formed on a diffusion layer L formed in the substrate 41 and includes a first lower insulating film 42a, a source-side conductive layer 42b, and a second lower insulating film 42c which are formed in sequence on the substrate 41. The memory holes M penetrate through the source-side conductive layer 42b. The first lower insulating film 42a is a silicon oxide film (SiO), for instance. The source-side conductive layer 42b is a polysilicon layer, for instance. The second lower insulating film 42c is a silicon oxide film, for instance.

The electrode layers 43 and the insulating layers 44 are alternately stacked on the lower layer 42. The electrode layers 43 are metal layers such as tungsten (W) layers or molybdenum (Mo) layers or semiconductor layers such as polysilicon layers, for instance, and function as word lines. The insulating layers 44 are silicon oxide films, for instance. The semiconductor device 40 includes: the memory holes M penetrating through the stacked film including the electrode layers 43 and the insulating layers 44; and the contact holes H formed on a stepped region of the stacked film including the electrode layers 43 and the insulating layers 44.

The upper layer 45 is on the aforesaid stacked film including the electrode layers 43 and the insulating layers 44 and includes a cover insulating film 45a, a drain-side conductive layer 45b, a first interlayer insulating film 45c, and a second interlayer insulating film 45d. The drain-side conductive layer 45b is on the aforesaid stacked film. The drain-side conductive layer 45b is located in a region where the memory holes M are formed and has the memory holes M penetrate therethrough. The cover insulating film 45a covers the tops of the stepped region of the stacked film and the drain-side conductive layer 45b. The first interlayer insulating film 45c is on the cover insulating film 45a to fill a space on the stepped region. The second interlayer insulating film 45d is on the cover insulating film 45a and the first interlayer insulating film 45c. The cover insulating film 45a is a stacked film of a silicon oxide film and a silicon nitride film, for instance. The first interlayer insulating film 45c and the second interlayer insulating film 45d are silicon oxide films, for instance. The drain-side conductive layer 45b is a polysilicon layer, for instance.

The block insulating film 51, the charge storage film 52, the tunnel insulating film 53, the channel semiconductor layer 54, and the core insulating film 55 are formed in sequence on a side surface of each of the memory holes M penetrating through the lower layer 42, the electrode layers 43, the insulating layers 44, and the upper layer 45. Based on such a structure, a plurality of memory cells are formed in the Z direction in each of the memory holes M. The block insulating films 51 are silicon oxide films, for instance. The charge storage films 52 are silicon nitride films (SiN), for instance. However, the charge storage films 52 may be semiconductor layers such as polysilicon layers. The tunnel insulating films 53 are silicon oxide films, for instance. The channel semiconductor layers 54 are semiconductor layers such as polysilicon layers and are electrically connected to the diffusion layer L formed in the substrate 41. The core insulating films 55 are silicon oxide films, for instance.

In the upper layer 45, the contact holes H penetrating therethrough are arranged in sequence along the stepped region. The contact plugs 56 are formed in the contact holes H. The contact plugs 56 are each electrically connected to a different electrode layer 43 out of the electrode layers 43 arranged stepwise. The contact plugs 56 are each formed of a barrier metal layer such as a titanium (Ti)-containing layer or a tantalum (Ta)-containing layer and a plug material layer such as a tungsten layer, a copper (Cu) layer, or an aluminum (Al) layer.

In the manufacture of the above-described semiconductor device 40, the plasma etching method of the embodiment is employed for forming the contact holes H, for instance. The contact plugs 56 are each electrically connected to a different electrode layer 43 out of the electrode layers 43 arranged stepwise. Accordingly, out of the contact holes H where to form the contact plugs 56, the contact hole H connected to a lower-side electrode layer 43 out of the electrode layers 43 arranged stepwise has a higher aspect ratio. In the formation of such a contact hole H with a high aspect ratio, it is important to form the contact hole H by plasma-etching the upper layer 45 made of the silicon oxide film or the like while keeping a processing selection ratio of the upper layer 45 made of the silicon oxide film or the like high with respect to the metal layer such as the W layer or the Mo layer forming the electrode layer 45.

In the formation of such a contact hole H, the plasma etching method of the embodiment achieves a good hole etching rate and can increase the processing selection ratio of the silicon-containing film with respect to the metal layer or the like, and further can favorably etch the silicon-containing film while avoiding the closing of the mask hole. The use of such a plasma etching method of the embodiment enables the efficient and accurate formation of the contact hole H with a high aspect ratio. This can increase manufacturing yields and productivity of the semiconductor device 40. The plasma etching method of the embodiment is also applicable to the formation of the memory holes M and is applicable to the etching of silicon-containing films of various semiconductor devices.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A plasma etching method comprising etching a silicon-containing film using plasma of fluorocarbon gas,
wherein the fluorocarbon gas contains fluorocarbon which has a composition, regarding carbon and fluorine, represented by
a general formula: CₓF_{y},
where x and y are numbers satisfying x≥12 and x≥y, and
which includes two benzene rings bonded through a C—C single bond.

2. The method according to claim 1, wherein the silicon-containing film is on a metal film.

3. The method according to claim 1, further comprising:
vaporizing the fluorocarbon being a solid material at room temperature to obtain a vaporized component of the fluorocarbon; and
generating the plasma of the fluorocarbon gas containing the vaporized component of the fluorocarbon.

4. The method according to claim 1, wherein a ratio of the carbon to the fluorine in the fluorocarbon exceeds 1.

5. The method according to claim 1, wherein the fluorocarbon has a structure in which a carbon atom of one of the benzene rings and a carbon atom of the other benzene rings are single-bonded.

6. The method according to claim 1, wherein the fluorocarbon has a structure in which a carbon atom of one of the benzene rings and a carbon atom of the other benzene rings are bonded through a divalent carbon fluoride group.

7. The method according to claim 1, wherein the fluorocarbon is perfluorocarbon compound.

8. The method according to claim 1, wherein the fluorocarbon gas includes at least one selected from the group consisting of a C₁₂F₁₀ gas and a C₁₃F₁₂ gas.

9. The method according to claim 1, wherein the fluorocarbon has at least one structure selected from the group consisting of following structural formula (1), structural formula (2), and structural formula (3).

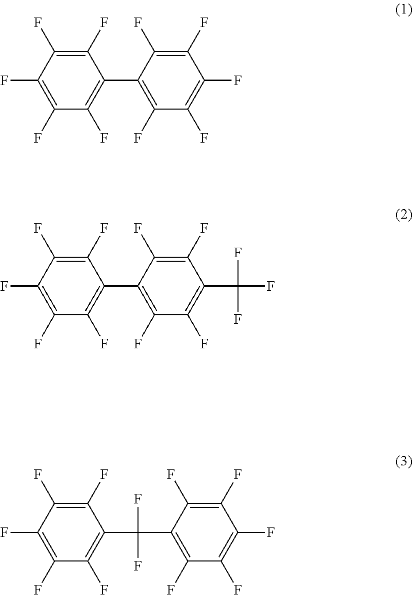 [SMILES: Fc1c(F)c(F)c(-c2c(F)c(F)c(F)c(F)c2F)c(F)c1F ; Fc1c(F)c(F)c(-c2c(F)c(F)c(C(F)(F)F)c(F)c2F)c(F)c1F ; Fc1c(F)c(F)c(C(F)(F)c2c(F)c(F)c(F)c(F)c2F)c(F)c1F]

10. The method according to claim 1, wherein:
the silicon-containing film includes a silicon oxide film or a stacked film of a silicon oxide film and a silicon nitride film, which is provided above a semiconductor substrate, and
the etching the silicon-containing film comprises: forming an etching mask having an opening on the silicon-containing film; and forming a hole corresponding to the opening in the silicon-containing film using the plasma of the fluorocarbon gas generated in a chamber.

11. The method according to claim 10, wherein the plasma of the fluorocarbon gas is generated by applying a high-frequency voltage between a first electrode which is in the chamber and on which the semiconductor substrate is placed and a second electrode which is in the chamber and faces the first electrode.

12. A plasma etching apparatus comprising:
a chamber in which a substrate to be etched is disposed;
an electrode disposed in the chamber;
a first process gas introducing unit including: a raw material tank storing a solid raw material of fluorocarbon which has a composition, regarding carbon and fluorine, represented by
a general formula: CₓF_{y},
where x and y are numbers satisfying x≥12 and x≥y, and
which includes two benzene rings bonded through a C—C single bond; and a vaporizing mechanism which vaporizes the solid raw material to introduce a fluorocarbon gas containing a vaporized component of the solid raw material, into the chamber; and
a power source which applies to the electrode a voltage for generating plasma of the fluorocarbon gas.

13. The apparatus according to claim 12, wherein
the vaporizing mechanism includes a first heater which is around the raw material tank to vaporize the solid raw material stored in the raw material tank, and
the first process gas introducing unit further includes: a gas flow rate controller which is in a pipe connecting the raw material tank and the chamber, to control a flow rate of the vaporized component of the solid raw material; and a second heater which is around the pipe.

14. A method for manufacturing a semiconductor device comprising:
forming a silicon-containing film on a base layer present above a semiconductor substrate;
forming an etching mask having an opening, on the silicon-containing film;
disposing the semiconductor substrate which the etching mask is formed on the silicon-containing film in a chamber; and
forming a hole corresponding to the opening in the silicon-containing film using plasma of a fluorocarbon gas generated in the chamber,
wherein the fluorocarbon gas contains fluorocarbon which has a composition, regarding carbon and fluorine, represented by
a general formula: CₓF_{y},
where x and y are numbers satisfying x≥12 and x≥y, and
which includes two benzene rings bonded through a C—C single bond.

15. The method according to claim 14, wherein the silicon-containing film is formed on a metal film as the base layer.

16. The method according to claim 15, wherein the silicon-containing film includes a silicon oxide film or a stacked film of a silicon oxide film and a silicon nitride film formed on the metal film.

17. The method according to claim 14, further comprising:
vaporizing the fluorocarbon being a solid material at room temperature to obtain a vaporized component of the fluorocarbon; and
generating the plasma of the fluorocarbon gas containing the vaporized component of the fluorocarbon.

18. The method according to claim 14, wherein a ratio of the carbon to the fluorine in the fluorocarbon exceeds 1.

19. The method according to claim 14, wherein the fluorocarbon is perfluorocarbon compound.

20. The method according to claim 14, wherein the fluorocarbon has at least one structure selected from the group consisting of following structural formula (1), structural formula (2), and structural formula (3). 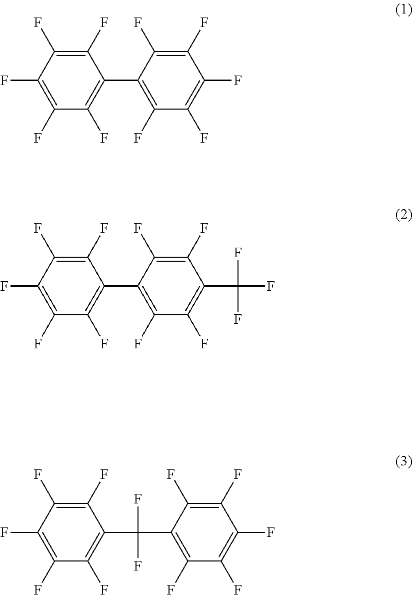 [SMILES: Fc1c(F)c(F)c(-c2c(F)c(F)c(F)c(F)c2F)c(F)c1F ; Fc1c(F)c(F)c(-c2c(F)c(F)c(C(F)(F)F)c(F)c2F)c(F)c1F ; Fc1c(F)c(F)c(C(F)(F)c2c(F)c(F)c(F)c(F)c2F)c(F)c1F]
